(19) United States
(12) Patent Application Publication
(10) Pub. No.: US 2025/0261470 A1
(43) Pub. Date: Aug. 14, 2025

(54) SYSTEMS AND METHODS FOR SMART SENSING THROUGH SENSOR/COMPUTE INTEGRATION

(71) Applicant: Meta Platforms Technologies, LLC, Menlo Park, CA (US)

(72) Inventors: Rajendra D Pendse, Fremont, CA (US); Andrew Samuel Berkovich, Sammamish, WA (US); Barbara De Salvo, Belmont, CA (US); Xinqiao Liu, Medina, WA (US); Clare Joyce Robinson, Bellevue, WA (US); Tsung-Hsun Tsai, Redmond, WA (US); Syed Shakib Sarwar, Bellevue, WA (US)

(21) Appl. No.: 19/048,418

(22) Filed: Feb. 7, 2025

Related U.S. Application Data
(60) Provisional application No. 63/551,146, filed on Feb. 8, 2024.

(51) Int. Cl. H10F 39/00; H01L 23/00; H01L 23/538; H01L 25/00; H01L 25/16; H10F 39/95

(52) U.S. Cl. CPC H10F 39/811; H01L 23/5385; H01L 24/48; H01L 25/167; H10F 39/95; H01L 24/16; H01L 24/32; H01L 24/73; H01L 25/50; H01L 2224/16227; H01L 2224/32227; H01L 2224/48227; H01L 2224/73204

(57) ABSTRACT

The disclosed semiconductor device package may include a compute chip configured to perform contextual artificial intelligence and machine perception operations. The disclosed semiconductor device package may additionally include a sensor positioned above the compute chip in the semiconductor device package. The disclosed semiconductor device package may also include one or more electrical connections configured to facilitate communication between the compute chip and the sensor, between the compute chip and a printed circuit board, and between the sensor and the printed circuit board. Various other methods, systems, and computer-readable media are also disclosed.

### CROSS REFERENCE TO RELATED APPLICATION

This application claims the benefit of U.S. Provisional Application No. 63/551,146, filed Feb. 8, 2024, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of exemplary methods for smart sensing through sensor/compute integration.

FIG. 2 illustrates systems and methods for smart sensing through sensor/compute integration.

FIG. 3 illustrates sensor compute co-package structure according to the disclosed systems and methods for smart sensing through sensor/compute integration.

FIG. 4 illustrates an example physical structure of a sensor/compute co-package according to the disclosed systems and methods for smart sensing through sensor/compute integration.

FIG. 5 illustrates chip on board (COB) chiplet co-packaging schemes according to the disclosed systems and methods for smart sensing through sensor/compute integration.

FIG. 6A illustrates chip on board/chip scale package (COB/CSP) chiplet co-packaging schemes according to the disclosed systems and methods for smart sensing through sensor/compute integration.

FIG. 6B illustrates chip on board/chip scale package (COB/CSP) chiplet co-packaging schemes according to the disclosed systems and methods for smart sensing through sensor/compute integration.

FIG. 7 illustrates chip scale package (CSP) chiplet co-packaging schemes according to the disclosed systems and methods for smart sensing through sensor/compute integration.

FIG. 8 is an illustration of example augmented-reality glasses that include an image sensor package with an additional connector attached to another sensor.

FIG. 9A is an illustration of an image sensor package having a connector for attachment to a system on chip.

FIG. 9B is an illustration of an image sensor package having an additional connector for attachment to an additional sensor.

FIG. 10 is an illustration of exemplary augmented-reality glasses that may be used in connection with embodiments of this disclosure.

FIG. 11 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

In the existing technology, camera modules house a single image sensor chip which is driven by a remotely positioned processor chip (also known as the “Main processor” or “Application Processor”). This architecture limits the implementation of “smart sensing” features like Contextual Artificial Intelligence (AI) (CAI) and Machine Perception (MP). These CAI and MP features, if made possible, can enrich user experience.

The present disclosure is generally directed to systems and methods for smart sensing through sensor/compute integration. The disclosed systems and methods can enable smart sensing features like CAI and MP without compromising form factor (FF) or power consumption. For example, a compute chip can be paired with an image sensor chip thru a novel stacked chiplet co-packaging scheme. The local presence of the compute chip can enable features like CAI and MP, thereby effectively making the image sensor “smart.” The novel stacked co-packaging scheme can ensure comparable FF to the case of a stand-alone image sensor while providing a short electrical path between the image sensor chip and the compute chip. This short electrical path can make it possible to realize the CAI and MP features with little to no power consumption penalty.

Benefits realized by the disclosed systems and methods can include a new way to make image sensors “smart” (i.e., to enable contextual AI and machine perception) without compromising form factor (i.e., size) or power consumption. Additionally, compared to an alternative approach that involves integrating the compute function into the image sensor chip as a separate chip layer to form a monolithic chip structure, the disclosed systems and methods can allow integration of the compute function at the package level versus at the chip level. This integration at the package level can enable an easier productization path as well as applicability to a broad cross section of off the shelf (OTS) sensors without need for sensor chip customization. Those in the AR/VR field who use camera modules in their products as well as manufacturers of image sensor chips can benefit directly from the disclosed systems and methods. Further, the broader packaging industry can benefit from the disclosed co-packaging structures, including packaging companies and chip companies.

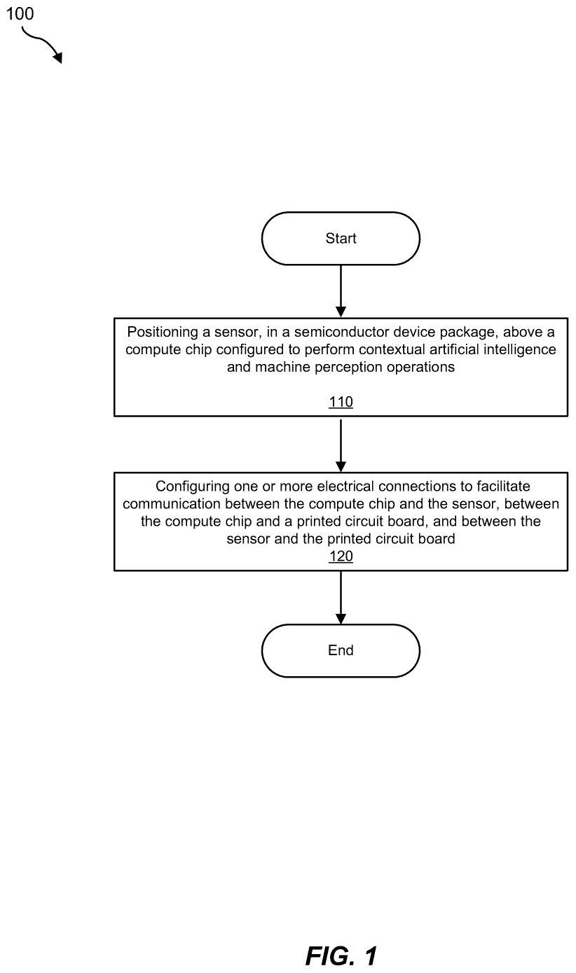

FIG. 1 illustrates methods 100 for smart sensing through sensor/compute integration. Method 100 may be carried out by humans and/or machines (e.g., workstations, chemical chambers, etc.) in various environments (e.g., clean rooms, etc.). Semiconductor device packages may be structured according to various packaging processes, such as substrate-level packaging processes or wafer-level packaging processes. For example, substrate-level packaging processes may employ a substrate to facilitate the assembly and connection of components on a base material. The substrate may ensure mechanical support, electrical pathways, and heat dissipation for integrated circuits (ICs) and electronic devices. Materials like silicon, ceramics, laminate structures, and organic compounds may be used based on specific needs.

Wafer-level packaging is a process in integrated circuit manufacturing in which packaging components may be attached to an integrated circuit (IC) before the wafer—on which the IC is fabricated—is diced. For example, the top and bottom layers of the packaging and the solder bumps may be attached to the integrated circuits while they are still in the wafer. This process differs from a process like substrate level packaging in which the wafer may be sliced into individual circuits (e.g., dice) before the packaging components are attached.

Chip on board (COB) is a method of circuit board manufacturing in which the integrated circuits (e.g. microprocessors) are attached (e.g., wired, bonded directly) to a printed circuit board, and covered by a blob of epoxy. COB eliminates the packaging of individual semiconductor devices, which allows a completed product to be less costly, lighter, and more compact. In some cases, COB construction improves the operation of radio frequency systems by reducing the inductance and capacitance of integrated circuit leads. COB effectively merges two levels of electronic packaging: level 1 (components) and level 2 (wiring boards), and may be referred to as “level 1.5”.

Chip scale package (CSP) refers to a type of integrated circuit (IC) package that is surface mountable and has an area not more than 1.2 times the original die area. IPC/JEDEC's standard J-STD-012 for Implementation of Flip Chip and Chip Scale Technology states that to qualify as a chip scale package, the chip must be a single-die and have a ball pitch of not more than 1 mm. More generally, any package that meets the dimensional requirements of the definition and has surface mount ability may be considered a CSP.

The term “sensor,” as used herein, may generally refer to a device that produces an output signal for the purpose of detecting a physical phenomenon. For example, and without limitation, a sensor may be a device, module, machine, or subsystem that detects events or changes in its environment and sends the information to other electronics, frequently a computer processor. In this context, an image sensor may detect and convey information used to form an image by converting the variable attenuation of light waves (as they pass through or reflect off objects) into signals (e.g., small bursts of current) that convey the information. The waves can be light or other electromagnetic radiation. Image sensors may used in electronic imaging devices of both analog and digital types, which include augmented-reality glasses, virtual-reality headsets, digital cameras, camera modules, camera phones, optical mouse devices, medical imaging equipment, night vision equipment such as thermal imaging devices, radar, sonar, and others.

The term “compute chip,” as used herein, may generally refer to a compute chiplet corresponding to a small, modular integrated circuit that can be combined with other chiplets to create a more complex system, such as a computer processor. For example, and without limitation, a compute chip may be configured to perform contextual artificial intelligence and machine perception operations. In this context, contextual artificial intelligence may be a type of AI that uses context to provide personalized and relevant responses by considering a variety of factors, such as location, preferences, and past interactions. Additionally, machine perception may use sensors, such as cameras and microphones, to gather data from the environment, analyze the data, and draw conclusions, thus allowing computers to learn and react like humans.

The term “electrical connections,” as used herein, may generally refer to devices that provide pathways for the passage of electrical energy and/or electric signals. For example, and without limitation, electrical connections may include wire bonds, metal layers, redistribution layers, electrical traces, ball grid arrays (e.g., copper balls), vias (e.g., copper pillars), through silicon vias, etc. In this contexts, wire bonding may involve wires (e.g., metal, copper, aluminum, etc.) attached between (e.g., faces of) semiconductor dies and packaging. In this context, wire bonds may be thin metallic bond wires, typically made of gold, aluminum, or copper, that are thermally or ultrasonically connected to chip terminals on one end, and to another semiconductor device component on the other end. Additionally, mounting (e.g., face down mounting) of chips/dies may involve ball grid arrays (e.g., metal (e.g., copper) balls) attached between (e.g., faces of) semiconductor dies and electrical traces and/or metal layers of printed circuit boards, redistribution layers, etc. Also, redistribution layers may be implemented in fan out wafer level (FWLP) packages that may include redistribution layers on one or both sides of a die, and multiple sets of redistribution layers may be connected, for example, by vias (e.g., copper pillars).

As shown in FIG. 1 at step 110, method 100 may include positioning a sensor. For example, method 100 may, at step 110, include positioning a sensor, in a semiconductor device package, above a compute chip configured to perform contextual artificial intelligence and machine perception operations.

Method 100 may, at step 110, position a sensor in various ways. In one example, method 100, at step 110, may include attaching the sensor, in the semiconductor device package, above the compute chip by an adhesive (e.g., directly, back-to-back, etc.). In another example, method 100, at step 110, may include attaching the sensor, in the semiconductor device package, above the compute chip by an adhesive to one or more redistribution layers positioned between the sensor and the compute chip. In another example, method 100, at step 110, may include attaching the sensor, in the semiconductor device package, above the compute chip by an adhesive to a package substrate positioned between the sensor and the compute chip. In another example, method 100, at step 110, may include attaching the sensor, in the semiconductor device package, above the compute chip by through silicon vias to a first set of one or more redistribution layers mounted atop a second set of redistribution layers positioned between the sensor and the compute chip. In another example, method 100, at step 110, may include attaching the sensor, in the semiconductor device package, above the compute chip by through silicon vias to one or more redistribution layers mounted atop a package substrate positioned between the sensor and the compute chip. In another example, method 100, at step 110, may include attaching the sensor, in the semiconductor device package, above the compute chip by through silicon vias to one or more redistribution layers positioned between the sensor and the compute chip.

As shown in FIG. 1 at step 120, method 100 may include configuring one or more electrical connections. For example, method 100 may, at step 120, include configuring one or more electrical connections to facilitate communication between the compute chip and the sensor, between the compute chip and a printed circuit board, and between the sensor and the printed circuit board.

Method 100 may, at step 120, configure one or more electrical connections in various ways. For example, method 100, at step 120, may include configuring one or more electrical connections that include wire bonding of the sensor and/or the compute chip to the printed circuit board, a package substrate, and/or one or more redistribution layers. Alternatively or additionally, method 100, at step 120, may include configuring one or more electrical connections that include face down mounting of the compute chip to at least one of the printed circuit board or one or more redistribution layers. Alternatively or additionally, method 100, at step 120, may include configuring one or more electrical connections that include through silicon via connection of the sensor to one or more redistribution layers.

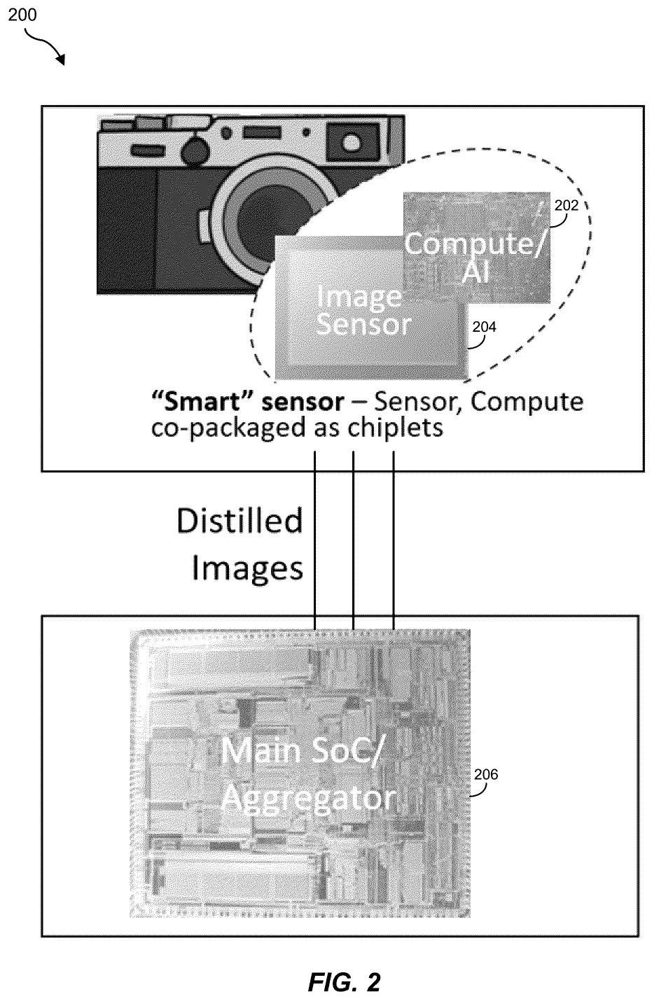

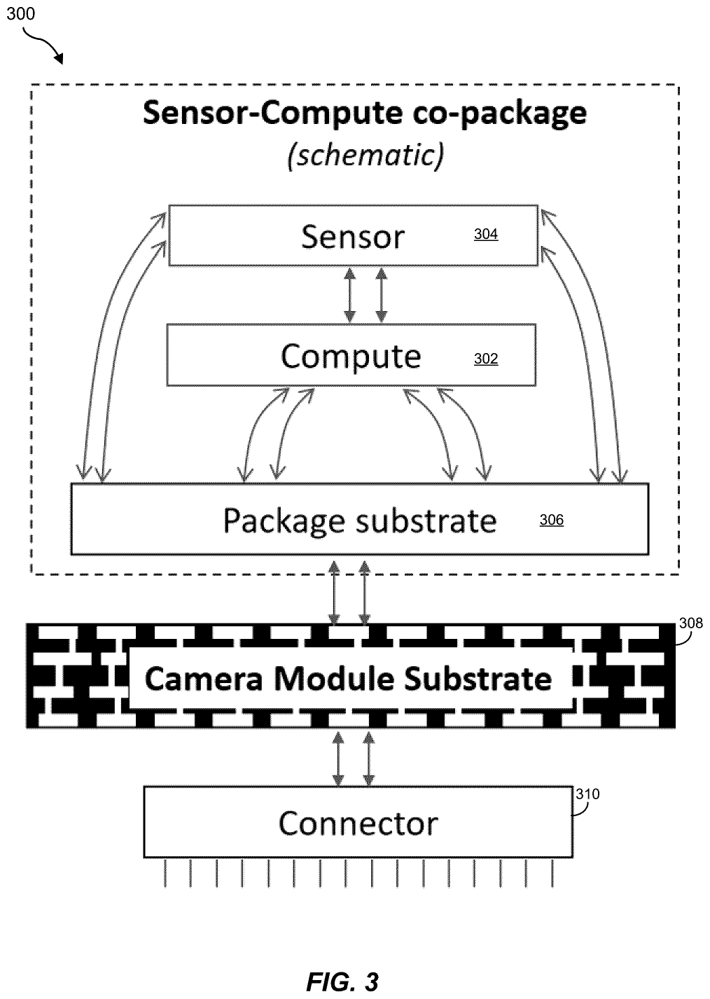

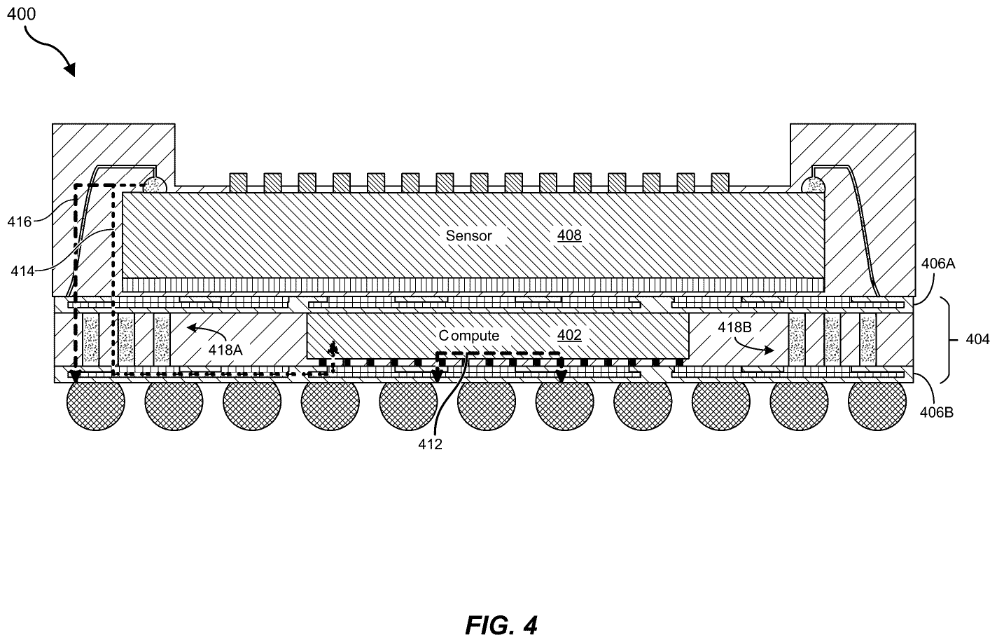

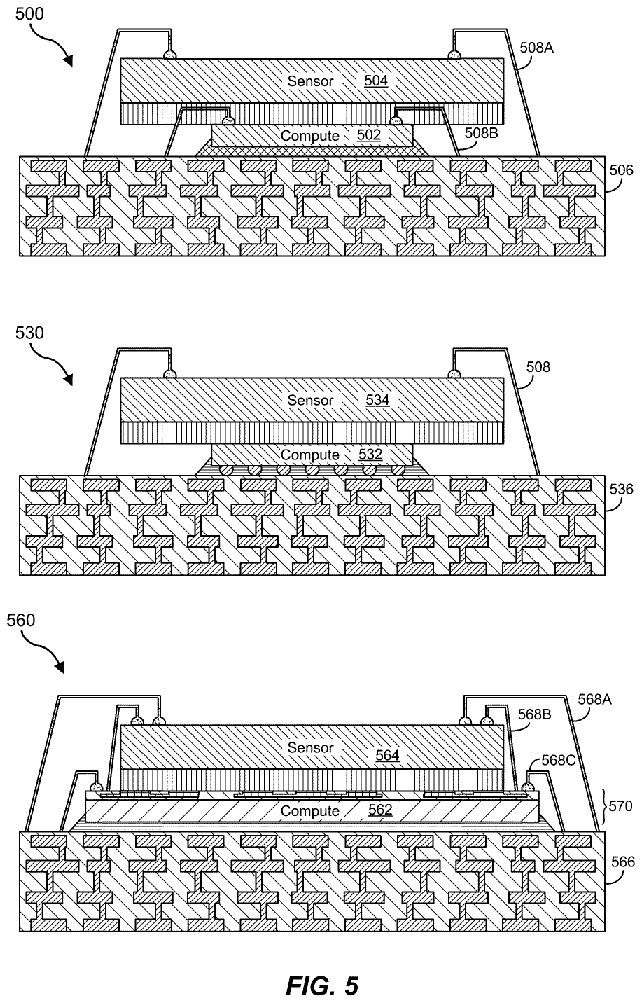

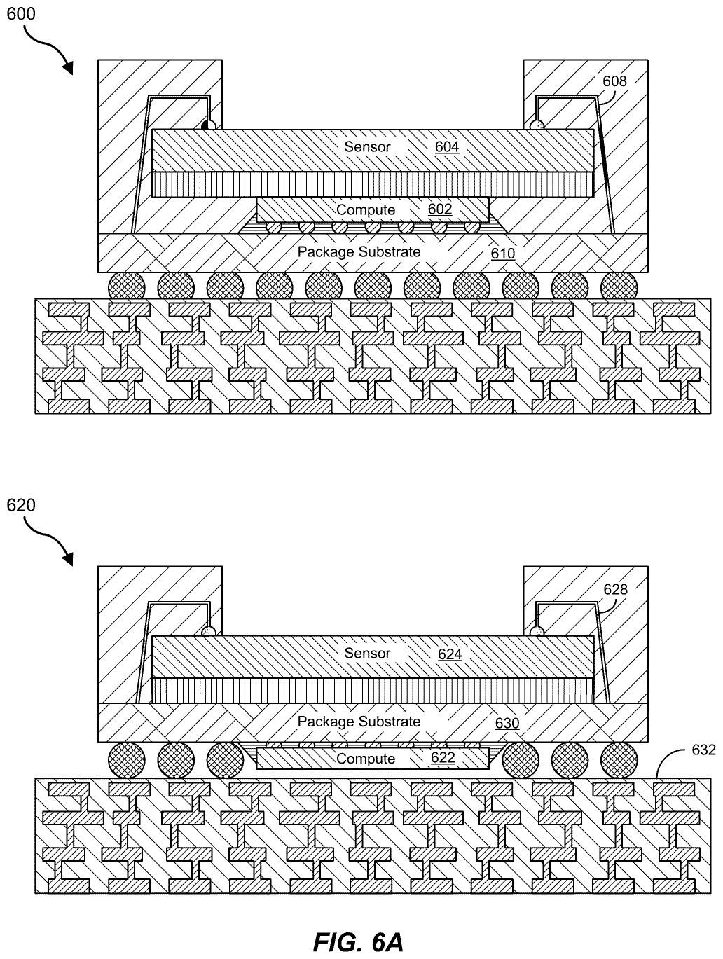

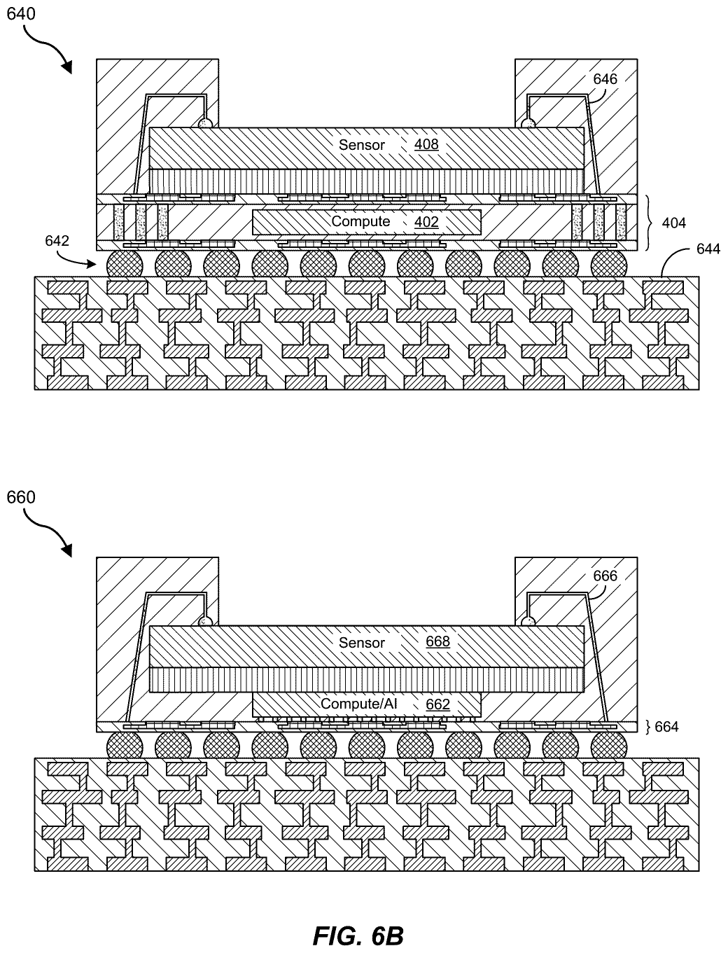

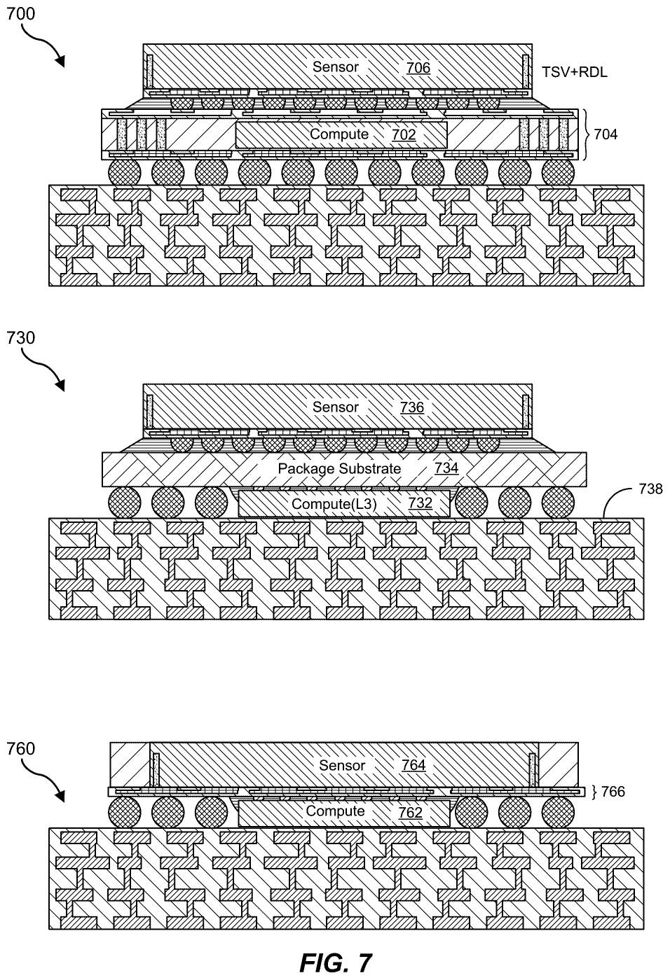

Example semiconductor devices and semiconductor device packages formed as a result of one or more implementations of method 100 are detailed herein with reference to FIGS. 2-7. For example, details of example systems and methods for smart sensing through sensor/compute integration are provided with reference to FIG. 2. Additionally, example sensor compute co-package structures are provided with reference to FIG. 3. Also, details of an example physical structure of a sensor/compute co-package are provided with reference to FIG. 4. Further, details of chip on board (COB) chiplet co-packaging schemes are provided with reference to FIG. 5. Further, details of chip on board/chip scale package (COB/CSP) chiplet co-packaging schemes are provided with reference to FIGS. 6A and 6B. Further, details of chip scale package (CSP) chiplet co-packaging schemes are provided with reference to FIG. 7.

FIG. 2 illustrates systems and methods for smart sensing through sensor/compute integration. As shown in FIG. 2, the disclosed smart sensor 200 can co-package a compute/AI 202 with an image sensor 204 as chiplets that provide distilled images to a main SoC aggregator chip 206. As one example, the smart sensor 200 can provide, as a distilled image, information of an imaged quick response (QR) code (e.g., a text message) rather than raw image data of the QR code. As a result, the disclosed smart sensor 200 can achieve reduced data transfer bandwidth (e.g., by a factor of one hundred) with consequent power consumption and latency improvements (e.g., by a factor of ten to one-hundred depending on sensor/compute interface design and signal path impedance to a main SoC). Additionally, the disclosed smart sensor 200 can realize machine perception (MP) and contextual AI (CAI) by enabling hand/eye tracking and/or other use cases by virtue of localizing compute/AI 202 function with the sensor 204.

FIG. 3 illustrates sensor compute co-package structure 300 according to the disclosed systems and methods for smart sensing through sensor/compute integration. As shown in FIG. 3, a compute chiplet 302 can be mounted between a sensor chiplet 304 and a package substrate 306. The sensor chiplet 304 and the compute chiplet 302 can be connected to the package substrate 306 by ball grid arrays (BGAs) and to one another, and these connections can be configured in various ways as detailed later with reference to FIGS. 4-7. Also, the package substrate 306 can communicate with a camera module substrate 308 which can, in turn, communicate with a connector 310. In this way, the sensor chiplet 304 and compute chiplet 302 can be integrated in a form factor package to create an intelligent (e.g., smart) AI-powered sensor. Further, this package can encompass all wiring between the sensor chiplet 304 and compute chiplet 302, between the sensor chiplet 304 and the external world (e.g., printed circuit board (e.g., camera module substrate 308), and between the compute chiplet 304 and the external world (e.g., printed circuit board (e.g., camera module substrate 308).

FIG. 4 illustrates an example physical structure of a sensor/compute co-package 400 according to the disclosed systems and methods. In this example, the compute chiplet 402 can be included in a fan-out wafer-level package (FOWLP) 404 having upper and lower redistribution layers (RDL) 406A and 406B. Inclusion of the compute chiplet 402 in the FOWLP 404 can allow the compute chiplet 402 and the sensor chiplet 408 to be of different sizes without causing structural issues in the package 400. The sensor chiplet 408 can be face up in all of the implementations disclosed herein so that it can sense light entering through an aperture in a mold material 410 holding the sensor chiplet 408 in place in the package 400. This mold material 410 can be formed using a cavity molding process (e.g., film assisted molding (FAM)). The BGA arranged at a periphery of an upper face of the sensor chiplet 408 can be connected to the upper RDL 406A of the FOWLP 404 by wire bonding. The compute chiplet 402 can be arranged face up or face down in the FOWLP 404 and its BGA can be connected to the upper or lower RDL layer of the FOWLP 404.

In the example shown in FIG. 4, the BGA of the compute chiplet 402 can be connected to the lower RDL 406B of the FOWLP 404. The connection 412 of the compute chiplet 402 to the external world can, thus, be through the lower RDL 406B layer of the FOWLP 404, and the connection 414 of the sensor chiplet 408 to the compute chiplet 402 can be by wire bonds to the upper RDL 406A of the FOWLP 404, through vias 418A and 418B (e.g., copper pillars) of the FOWLP 404 to the lower RDL 406B of the FOWLP 404, and through the lower RDL 406B of the FOWLP 404 to the compute chiplet 402 by the BGA of the compute chiplet 402 that is connected to the lower RDL 406B of the FOWLP 404. In turn, the connection 416 of the sensor chiplet 408 to the external world can be by the wire bonds to the upper RDL 406A of the FOWLP 404, through vias 418A and 418B (e.g., copper pillars) of the FOWLP 404 to the lower RDL 406B of the FOWLP 404, and through the lower RDL 406B of the FOWLP 404 to the BGA of the package substrate. As in FIG. 2, the sensor chiplet 408 and compute chiplet 402 can be integrated in a form factor package to create an intelligent (e.g., smart) AI-powered sensor. Further, this package 400 can encompass all wiring between the sensor chiplet 408 and compute chiplet 402, between the sensor chiplet 408 and the external world, and between the compute chiplet 402 and the external world.

FIG. 5 illustrates COB chiplet co-packaging schemes 500, 530, and 560 that involve components that are designed for connection by wire bonding and thus can be implemented by a contract manufacturer. The wire bonds can be protected by global molding formed using cavity molding in which a thin film prevents the mold from contacting the sensor imaging components. The thin film can also increase sensor life by preventing degradation of the metal.

As shown in FIG. 5, COB co-packaging scheme 500 inserts a compute chiplet 502 in a face up configuration between a sensor chiplet 504 and a module substrate 506. COB co-packaging scheme 500 employs wire bonding 508A and 508B to connect both the sensor chiplet 504 and the compute chiplet 502 to the outside world and to one another through the module substrate 506. COB co-packaging scheme 500 affects communication between the compute chiplet 502 and the sensor chiplet 504 by a signal pathway that extends through the wire bonds from the sensor chiplet 504 to the module substrate 506 and laterally through layers of the module substrate 506 to a BGA on a face of the flipped face down compute chiplet 502.

As shown in FIG. 5, COB co-packaging scheme 530 inserts a compute chiplet 532 in a flip chip configuration between a sensor chiplet 534 and a module substrate 536. COB co-packaging scheme 530 employs wire bonding 508 to connect the sensor chiplet 534 to the module substrate 536 and the compute chiplet 532 is connected to the module substrate 536 by a BGA. COB co-packaging scheme 530 affects communication between the compute chiplet 532 and the sensor chiplet 534 by a signal pathway that extends through the wire bonds from the sensor chiplet 534 to the module substrate 536 and laterally through layers of the module substrate 536 to the BGA on the face of the flipped face down compute chiplet 532.

As shown in FIG. 5, COB co-packaging scheme 560 inserts a compute chiplet 562 in a FOWLP 570 that has an upper RDL but not a lower RDL, with wire bonding 568A and 568C of both the sensor chiplet 564 and the FOWLP 570 to the module substrate 566. In this case, the compute chiplet 562 can be packaged in the FOWLP 570 by a silicon packaging house and provided to a contract manufacturer in the form of a chip that can be wire bonded. The compute chiplet 562 can be face up in the FOWLP 570 with wire bonding 568B of the sensor chiplet to the upper RDL of the FOWLP as shown in FIG. 5. In this case, COB co-packaging scheme 560 can affect communication between the sensor chiplet 564 and the compute chiplet 562 by a signal pathway that extends through these wire bonds to the upper RDL layer and laterally through the RDL layer to a BGA on the face of the compute chiplet 562.

FIGS. 6A and 6B illustrate COB/CSP chiplet co-packaging schemes 600, 620, 640, and 660 that involve packaging of sensor chiplets designed as wire bond chiplets but that are packaged with compute chiplets into packages that can then be mounted on a module substrate. The wire bonds can be protected by global molding formed using cavity molding in which a thin film prevents the mold from contacting the sensor imaging components. The thin film can also increase sensor life by preventing degradation of the metal.

As shown in FIG. 6A, COB/CSP chiplet co-packaging schemes 600 and 620 both use a packaging substrate 610 and 630 to which a compute chiplet 602 and 622 is connected and the sensor chiplet 604 and 624 is connected by wire bonding 608 and 628 to the packaging substrate 610 and 630. In COB/CSP chiplet co-packaging scheme 600, the compute chiplet 602 can be flipped face down and connected to the package substrate 610 by a BGA on a face of the compute chiplet 602. In COB/CSP chiplet co-packaging scheme 620, the compute chiplet 622 can be connected face up to an underside (e.g., marsupial design) of the package substrate 630 by a BGA on a face of the compute chiplet 622. This marsupial design has an advantage of reducing thickness of the overall package, but a larger compute chiplet 622 can require increase in footprint of the package due to expanding the package substrate 630 to accommodate BGA thereof for connection to the module substrate 632. Thus, COB/CSP chiplet co-packaging scheme 620 may be utilized when a sensor chiplet 624 is co-packaged with a compute chiplet 622 having a smaller footprint than a footprint of the sensor chiplet 624.

As shown in FIG. 6B, COB/CSP chiplet co-packaging scheme 640 can correspond to the example physical structure of a sensor/compute co-package 400 of FIG. 4 as detailed above. As previously mentioned, the FOWLP 404 of COB/CSP chiplet co-packaging scheme 640 has both upper and lower RDL with vias (e.g., copper pillars) providing connection therebetween. As a result, the compute chiplet 402 can be mounted face up or face down in the FOWLP 404, and the lower RDL can connect by bumps 642 to the module substrate 644. Mounting of the compute chiplet 402 face up can improve performance by shortening the communication pathways between the compute chiplet 402 and the sensor chiplet 408. In this case, the communication pathway between the sensor chiplet 408 and the compute chiplet 402 can extend through the wire bonding 646 from the sensor chiplet 408 to the upper RDL of the FOWLP 404 and laterally through the upper RDL to the BGA on the face of the face up compute chiplet 402. Benefits of using a FOWLP 404 can include accommodating various chiplet sizes, with the FOWLP 404 providing structural integrity for packages that house smaller footprint compute chiplets 402 and wire bonding 646 connection capabilities for packages that house smaller footprint sensor chiplets 408. The FOWLP 404 can also improve performance by providing increased wiring density.

As shown in FIG. 6, COB/CSP chiplet co-packaging scheme 660 employs a compute chiplet 662 flipped and mounted face down directly on an RDL 664. Compared to COB/CSP chiplet co-packaging scheme 600, COB/CSP chiplet co-packaging scheme 660 replaces the package substrate 610 of COB/CSP chiplet co-packaging scheme 600 with an RDL 664. This configuration has the benefit of reduced thickness. This configuration can be suitable when the compute chiplet 662 does not have a footprint sufficiently larger than a footprint of the sensor chiplet 668 that it becomes difficult to use wire bonding 666 to connect the sensor chiplet 668 to the RDL 664. This configuration can also be suitable when the sensor chiplet 668 does not have a footprint sufficiently larger than a footprint of the compute chiplet 662 that structural integrity of the package becomes an issue due to overhang of the compute chiplet 662 by the sensor chiplet 668. This configuration can be accomplished using a completely wafer level packaging process, which is distinguishable from a laminate based packaging process employed for COB/CSP chiplet co-packaging scheme 600. The RDL 664 also provides increased wiring density compared to a package substrate.

FIG. 7 illustrates CSP chiplet co-packaging schemes 700, 730, and 760 that involve packaging of sensor chiplets 702, 732, and 762 that are not designed for wire bonding. The consequent lack of any wire bonds can eliminate the need for global molding in CSP chiplet co-packaging schemes 700, 730, and 760. For example, CSP chiplet co-packaging scheme 700 only includes molding in a FOWLP 704 utilized therein. Similarly, CSP chiplet co-packaging scheme 760 can only include molding as needed to structurally support expansion of an RDL 766 for addition of pins as may be needed to accommodate marsupial mounting of a compute chiplet 762. The wire bonds are eliminated because the sensor chiplets 702, 732, and 762 have TSVs through a backside of the die that connect the sensor chiplets 702, 732, and 762 to RDLs that have BGAs.

As shown in FIG. 7, CSP chiplet co-packaging scheme 700 combines a compute chiplet 702 located in a FOWLP 704 with a sensor chiplet 706 located in a CSP package. In this case, connection routing can be through bumps of the CSP package containing the sensor chiplet 706 through RDL of the FOWLP 704 containing the compute chiplet 702. Depending on whether the compute chiplet 702 is face up or face down, the routing can go through the vias (e.g., copper pillars) of the FOWLP 704 or directly through the bumps of the compute chiplet 702.

As shown in FIG. 7, CSP chiplet co-packaging scheme 730 combines a compute chiplet 732 mounted face up on an underside of a package substrate 734 (e.g., marsupial design) with a sensor chiplet 736 located in a CSP package. As in the case of COB/CSP chiplet co-packaging scheme 720 of FIG. 7, this marsupial design has an advantage of reducing thickness of the overall package, but a larger compute chiplet 732 can require increase in footprint of the package due to expanding the package substrate 734 to accommodate BGA thereof for connection to the module substrate 738. Thus, CSP chiplet co-packaging scheme 730 may be utilized when the compute chiplet 732 has a smaller footprint than a footprint of the sensor chiplet 736 located in a CSP package.

As shown in FIG. 7, CSP chiplet co-packaging scheme 760 combines a compute chiplet 762 mounted face up on an underside of an RDL 766 (e.g., marsupial design) with a sensor chiplet 764 located in a CSP package. This configuration can achieve a reduced package height while accommodating manufacture using a completely wafer level packaging process that can drop the sensor chiplet 764 in place as an incremental step without requiring a separate process.

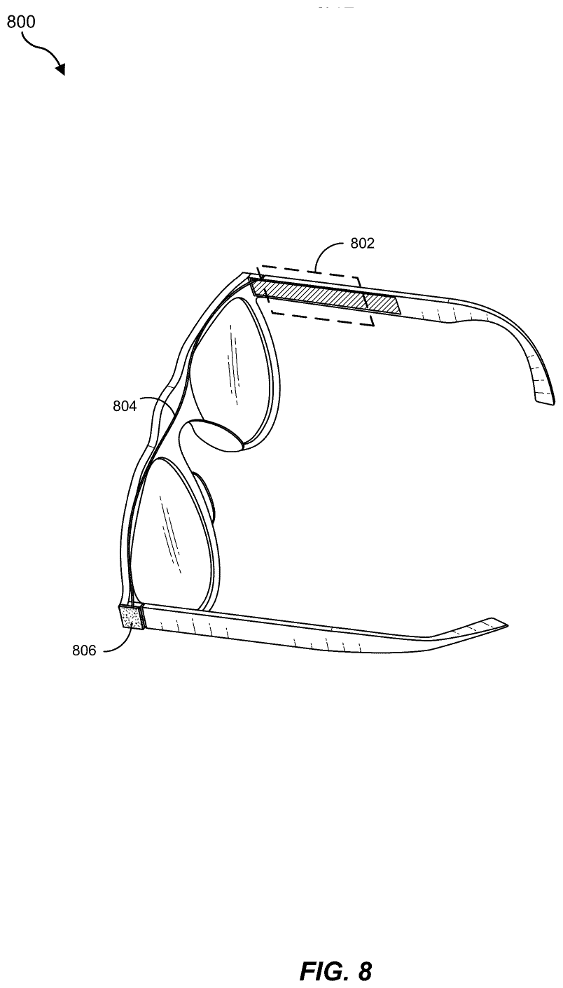

FIG. 8 illustrates example augmented-reality glasses 800 that include an image sensor package 802 with an additional connector 804 attached to another sensor 806. For example, the other sensor 806 may be another image sensor package or another type of sensor, such as a gyroscope, accelerometer, etc. Image sensor package 802 may also connect to an SOC (e.g., by connector 310 of FIG. 3) and may provide a connection to the SOC for the other sensor 806 via the additional connector 804. Alternatively or additionally, the additional connector 804 may connect the other sensor 806 to a compute chip of the image sensor package 802, which may perform processing for the other sensor 806. The additional connector 804 may, thus, connect other sensors 806 (e.g., daisy chain, etc.) to the image sensor package 802, which may be closer to a destination SOC.

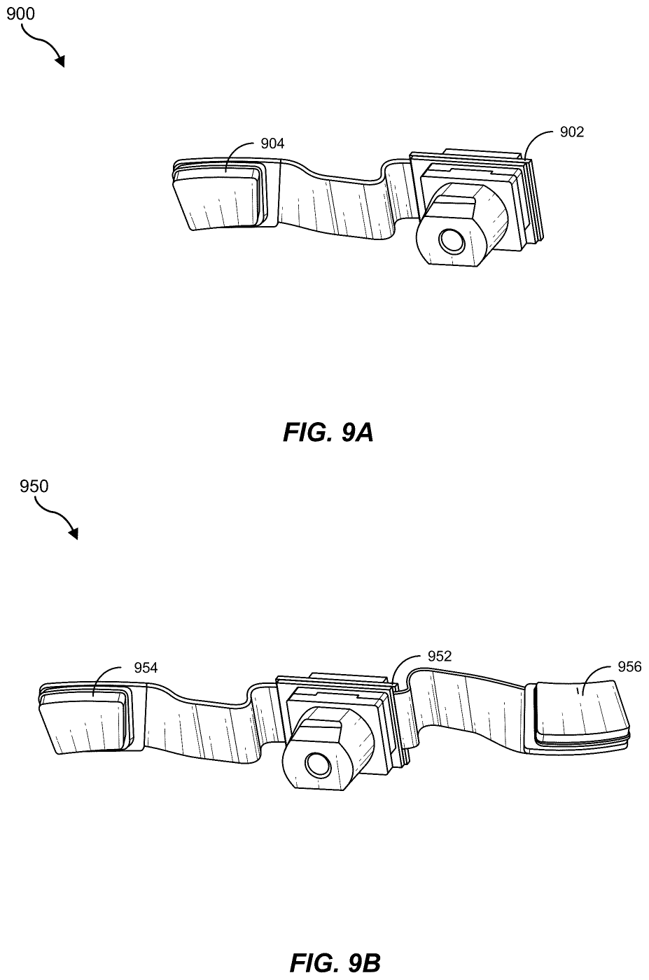

FIG. 9A illustrates an imaging system 900 that of an image sensor package 902 having a connector 954 (e.g., connector 310 of FIG. 3) for attachment to a system on chip (SOC). In contrast, FIG. 9B illustrates an image sensor package 952 having the connector 954 and an additional connector 956 for attachment to one or more other sensors. For example, the one or more other sensors may include one or more other image sensor packages and/or one or more other types of sensors, such as gyroscopes, accelerometers, etc. Image sensor package 952 may connect to an SOC by connector 954 and may provide a connection to the SOC for the one or more other sensors via the additional connector 956. Alternatively or additionally, the additional connector 956 may connect the one or more other sensors to a compute chip of the image sensor package 952, which may perform processing for the one or more other sensors. The compute chip of the image sensor package 952 may, for example, process data from the one or more other sensors and ship it to the SOC. Alternatively or additionally, The compute chip of the image sensor package 952 may fuse data from its own sensor with that of other sensors for multimodal sensor processing.

As set forth above, the discloses systems and methods may enable smart sensing features like CAI and MP without compromising form factor (FF) or power consumption. For example, a compute chip can be paired with an image sensor chip thru a novel stacked chiplet co-packaging scheme. The local presence of the compute chip can enable features like CAI and MP, thereby effectively making the image sensor “smart.” The novel stacked co-packaging scheme can ensure comparable FF to the case of a stand-alone image sensor while providing a short electrical path between the image sensor chip and the compute chip. This short electrical path can make it possible to realize the CAI and MP features with little to no power consumption penalty.

Benefits realized by the disclosed systems and methods can include a new way to make image sensors “smart” (i.e., to enable contextual AI and machine perception) without compromising form factor (i.e., size) or power consumption. Additionally, compared to an alternative approach that involves integrating the compute function into the image sensor chip as a separate chip layer to form a monolithic chip structure, the disclosed systems and methods can allow integration of the compute function at the package level versus at the chip level. This integration at the package level can enable an easier productization path as well as applicability to a broad cross section of off the shelf (OTS) sensors without need for sensor chip customization. Those in the AR/VR field who use camera modules in their products as well as manufacturers of image sensor chips can benefit directly from the disclosed systems and methods. Further, the broader packaging industry can benefit from the disclosed co-packaging structures, including packaging companies and chip companies.

### EXAMPLE EMBODIMENTS

Example 1: A semiconductor device package may include a compute chip configured to perform contextual artificial intelligence and machine perception operations, a sensor positioned above the compute chip in the semiconductor device package, and one or more electrical connections configured to facilitate communication between the compute chip and the sensor, between the compute chip and a printed circuit board, and between the sensor and the printed circuit board.

Example 2: The semiconductor device package of example 1, wherein the one or more electrical connections include wire bonding of sensor and compute chip to printed circuit board.

Example 3: The semiconductor device package of any of examples 1 or 2, wherein the one or more electrical connections include wire bonding of the sensor to the printed circuit board and face down mounting of the compute chip to the printed circuit board.

Example 4: The semiconductor device package of any of examples 1-3, wherein the one or more electrical connections include one or more redistribution layers positioned between the sensor and the compute chip, wire bonding of the sensor to the one or more redistribution layers, wire bonding of the sensor to the printed circuit board, and wire bonding of the one or more redistribution layers to the printed circuit board.

Example 5: The semiconductor device package of any of examples 1-4, wherein the one or more electrical connections include a package substrate positioned below the compute chip in the semiconductor device package, face down mounting of the compute chip to the package substrate, and wire bonding of the sensor to the package substrate.

Example 6: The semiconductor device package of any of examples 1-5, wherein the one or more electrical connections include a package substrate positioned between the sensor and the compute chip in the semiconductor device package, mounting of the compute chip to the package substrate, and wire bonding of the sensor to the package substrate.

Example 7: The semiconductor device package of any of examples 1-6, wherein the one or more electrical connections include a first set of one or more redistribution layers positioned between the sensor and the compute chip, a second set of one or more redistribution layers positioned below the compute chip, wire bonding of the sensor to the first set of one or more redistribution layers, and face down mounting of the compute chip to the second set of one more redistribution layers.

Example 8: The semiconductor device package of any of examples 1-7, wherein the one or more electrical connections include one or more redistribution layers positioned below the compute chip, wire bonding of the sensor to the one or more redistribution layers, and face down mounting of the compute chip to the one more redistribution layers.

Example 9: The semiconductor device package of any of examples 1-8, wherein the one or more electrical connections include a first set of one or more redistribution layers positioned between the sensor and the compute chip, a second set of one or more redistribution layers positioned below the compute chip, though silicon via connection of the sensor to the first set of one or more redistribution layers, and face down mounting of the compute chip to the second set of one more redistribution layers.

Example 10: The semiconductor device package of any of examples 1-9, wherein the one or more electrical connections include one or more redistribution layers positioned between the sensor and the compute chip, a package substrate positioned between the one or more redistribution layers, though silicon via connection of the sensor to the one or more redistribution layers, and mounting of the compute chip to the package substrate.

Example 11: The semiconductor device package of any of examples 1-10, wherein the one or more electrical connections include one or more redistribution layers positioned between the sensor and the compute chip, though silicon via connection of the sensor to the one or more redistribution layers, and mounting of the compute chip to the one or more redistribution layers.

Example 12: A semiconductor device may include a compute chip configured to perform contextual artificial intelligence and machine perception operations, and a sensor attached above the compute chip.

Example 13: The semiconductor device of example 12, wherein the sensor is attached to the compute chip by an adhesive.

Example 14: The semiconductor device of any of examples 12 or 13, wherein the sensor is attached by an adhesive to one or more redistribution layers positioned between the sensor and the compute chip.

Example 15: The semiconductor device of any of examples 12-14, wherein the sensor is attached by an adhesive to a package substrate positioned between the sensor and the compute chip.

Example 16: The semiconductor device of any of examples 12-15, wherein the sensor is attached by through silicon vias to a first set of one or more redistribution layers mounted atop a second set of redistribution layers positioned between the sensor and the compute chip.

Example 17: The semiconductor device of any of examples 12-16, wherein the sensor is attached by through silicon vias to one or more redistribution layers mounted atop a package substrate positioned between the sensor and the compute chip.

Example 18: The semiconductor device of any of examples 12-17, wherein the sensor is attached by through silicon vias to one or more redistribution layers positioned between the sensor and the compute chip.

Example 19: The semiconductor device of any of examples 12-18, further including a first connector configured to connect the semiconductor device to a system on chip and a second connector configured to connect the semiconductor device to another sensor.

Example 20: A method may include positioning a sensor, in a semiconductor device package, above a compute chip configured to perform contextual artificial intelligence and machine perception operations, and configuring one or more electrical connections to facilitate communication between the compute chip and the sensor, between the compute chip and a printed circuit board, and between the sensor and the printed circuit board.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

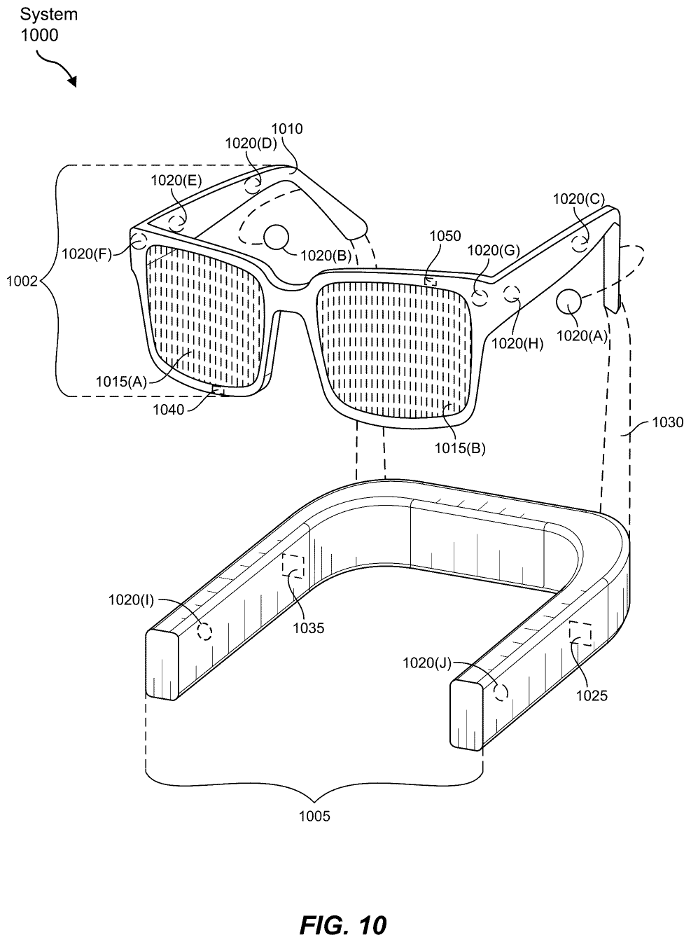

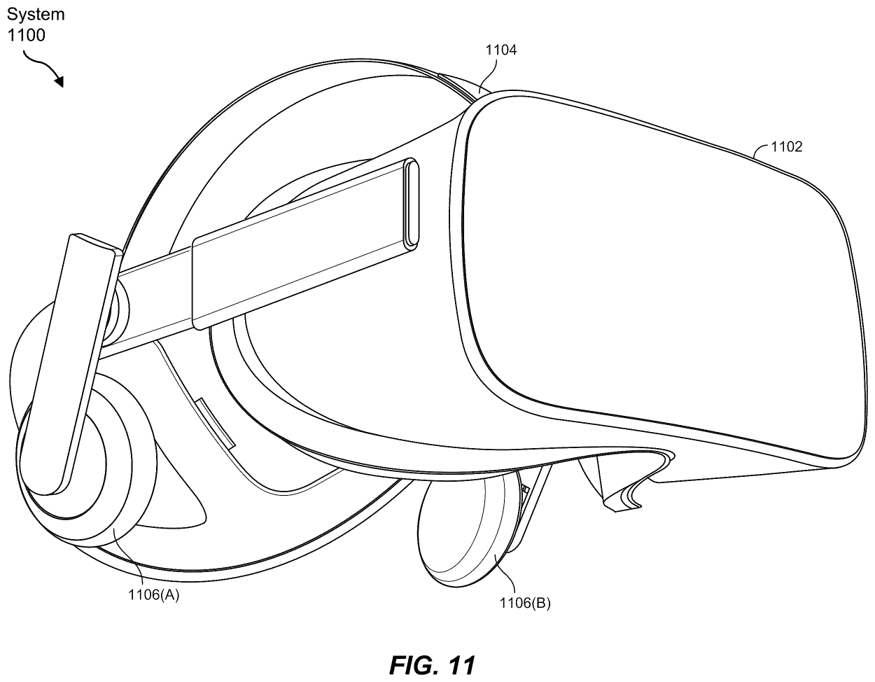

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 1000 in FIG. 10) or that visually immerses a user in an artificial reality (such as, e.g., virtual-reality system 1100 in FIG. 11). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

FIG. 10 is an illustration of exemplary augmented-reality glasses that may be used in connection with embodiments of this disclosure. As shown in FIG. 10, augmented-reality system 1000 may include an eyewear device 1002 with a frame 1010 configured to hold a left display device 1015(A) and a right display device 1015(B) in front of a user's eyes. Display devices 1015(A) and 1015(B) may act together or independently to present an image or series of images to a user. While augmented-reality system 1000 includes two displays, embodiments of this disclosure may be implemented in augmented-reality systems with a single NED or more than two NEDs.

In some embodiments, augmented-reality system 1000 may include one or more sensors, such as sensor 1040. Sensor 1040 may generate measurement signals in response to motion of augmented-reality system 1000 and may be located on substantially any portion of frame 1010. Sensor 1040 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1000 may or may not include sensor 1040 or may include more than one sensor. In embodiments in which sensor 1040 includes an IMU, the IMU may generate calibration data based on measurement signals from sensor 1040. Examples of sensor 1040 may include, without limitation, accelerometers, gyroscopes, magnetometers, other suitable types of sensors that detect motion, sensors used for error correction of the IMU, or some combination thereof.

In some examples, augmented-reality system 1000 may also include a microphone array with a plurality of acoustic transducers 1020(A)-1020(J), referred to collectively as acoustic transducers 1020. Acoustic transducers 1020 may represent transducers that detect air pressure variations induced by sound waves. Each acoustic transducer 1020 may be configured to detect sound and convert the detected sound into an electronic format (e.g., an analog or digital format). The microphone array in FIG. 10 may include, for example, ten acoustic transducers: 1020(A) and 1020(B), which may be designed to be placed inside a corresponding ear of the user, acoustic transducers 1020(C), 1020(D), 1020(E), 1020(F), 1020(G), and 1020(H), which may be positioned at various locations on frame 1010, and/or acoustic transducers 1020(I) and 1020(J), which may be positioned on a corresponding neckband 1005.

In some embodiments, one or more of acoustic transducers 1020(A)-(J) may be used as output transducers (e.g., speakers). For example, acoustic transducers 1020(A) and/or 1020(B) may be earbuds or any other suitable type of headphone or speaker.

The configuration of acoustic transducers 1020 of the microphone array may vary. While augmented-reality system 1000 is shown in FIG. 10 as having ten acoustic transducers 1020, the number of acoustic transducers 1020 may be greater or less than ten. In some embodiments, using higher numbers of acoustic transducers 1020 may increase the amount of audio information collected and/or the sensitivity and accuracy of the audio information. In contrast, using a lower number of acoustic transducers 1020 may decrease the computing power required by an associated controller 1050 to process the collected audio information. In addition, the position of each acoustic transducer 1020 of the microphone array may vary. For example, the position of an acoustic transducer 1020 may include a defined position on the user, a defined coordinate on frame 1010, an orientation associated with each acoustic transducer 1020, or some combination thereof.

Acoustic transducers 1020(A) and 1020(B) may be positioned on different parts of the user's ear, such as behind the pinna, behind the tragus, and/or within the auricle or fossa. Or, there may be additional acoustic transducers 1020 on or surrounding the ear in addition to acoustic transducers 1020 inside the ear canal. Having an acoustic transducer 1020 positioned next to an ear canal of a user may enable the microphone array to collect information on how sounds arrive at the ear canal. By positioning at least two of acoustic transducers 1020 on either side of a user's head (e.g., as binaural microphones), augmented-reality device 1000 may simulate binaural hearing and capture a 3D stereo sound field around about a user's head. In some embodiments, acoustic transducers 1020(A) and 1020(B) may be connected to augmented-reality system 1000 via a wired connection 1030, and in other embodiments acoustic transducers 1020(A) and 1020(B) may be connected to augmented-reality system 1000 via a wireless connection (e.g., a BLUETOOTH connection). In still other embodiments, acoustic transducers 1020(A) and 1020(B) may not be used at all in conjunction with augmented-reality system 1000.

Acoustic transducers 1020 on frame 1010 may be positioned in a variety of different ways, including along the length of the temples, across the bridge, above or below display devices 1015(A) and 1015(B), or some combination thereof. Acoustic transducers 1020 may also be oriented such that the microphone array is able to detect sounds in a wide range of directions surrounding the user wearing the augmented-reality system 1000. In some embodiments, an optimization process may be performed during manufacturing of augmented-reality system 1000 to determine relative positioning of each acoustic transducer 1020 in the microphone array.

In some examples, augmented-reality system 1000 may include or be connected to an external device (e.g., a paired device), such as neckband 1005. Neckband 1005 generally represents any type or form of paired device. Thus, the following discussion of neckband 1005 may also apply to various other paired devices, such as charging cases, smart watches, smart phones, wrist bands, other wearable devices, hand-held controllers, tablet computers, laptop computers, other external compute devices, etc.

As shown, neckband 1005 may be coupled to eyewear device 1002 via one or more connectors. The connectors may be wired or wireless and may include electrical and/or non-electrical (e.g., structural) components. In some cases, eyewear device 1002 and neckband 1005 may operate independently without any wired or wireless connection between them. While FIG. 10 illustrates the components of eyewear device 1002 and neckband 1005 in example locations on eyewear device 1002 and neckband 1005, the components may be located elsewhere and/or distributed differently on eyewear device 1002 and/or neckband 1005. In some embodiments, the components of eyewear device 1002 and neckband 1005 may be located on one or more additional peripheral devices paired with eyewear device 1002, neckband 1005, or some combination thereof.

Pairing external devices, such as neckband 1005, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1000 may be provided by a paired device or shared between a paired device and an eyewear device, thus reducing the weight, heat profile, and form factor of the eyewear device overall while still retaining desired functionality. For example, neckband 1005 may allow components that would otherwise be included on an eyewear device to be included in neckband 1005 since users may tolerate a heavier weight load on their shoulders than they would tolerate on their heads. Neckband 1005 may also have a larger surface area over which to diffuse and disperse heat to the ambient environment. Thus, neckband 1005 may allow for greater battery and computation capacity than might otherwise have been possible on a stand-alone eyewear device. Since weight carried in neckband 1005 may be less invasive to a user than weight carried in eyewear device 1002, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1005 may be communicatively coupled with eyewear device 1002 and/or to other devices. These other devices may provide certain functions (e.g., tracking, localizing, depth mapping, processing, storage, etc.) to augmented-reality system 1000. In the embodiment of FIG. 10, neckband 1005 may include two acoustic transducers (e.g., 1020(I) and 1020(J)) that are part of the microphone array (or potentially form their own microphone subarray). Neckband 1005 may also include a controller 1025 and a power source 1035.

Acoustic transducers 1020(I) and 1020(J) of neckband 1005 may be configured to detect sound and convert the detected sound into an electronic format (analog or digital). In the embodiment of FIG. 10, acoustic transducers 1020(I) and 1020(J) may be positioned on neckband 1005, thereby increasing the distance between the neckband acoustic transducers 1020(I) and 1020(J) and other acoustic transducers 1020 positioned on eyewear device 1002. In some cases, increasing the distance between acoustic transducers 1020 of the microphone array may improve the accuracy of beamforming performed via the microphone array. For example, if a sound is detected by acoustic transducers 1020(C) and 1020(D) and the distance between acoustic transducers 1020(C) and 1020(D) is greater than, e.g., the distance between acoustic transducers 1020(D) and 1020(E), the determined source location of the detected sound may be more accurate than if the sound had been detected by acoustic transducers 1020(D) and 1020(E).

Controller 1025 of neckband 1005 may process information generated by the sensors on neckband 1005 and/or augmented-reality system 1000. For example, controller 1025 may process information from the microphone array that describes sounds detected by the microphone array. For each detected sound, controller 1025 may perform a direction-of-arrival (DOA) estimation to estimate a direction from which the detected sound arrived at the microphone array. As the microphone array detects sounds, controller 1025 may populate an audio data set with the information. In embodiments in which augmented-reality system 1000 includes an inertial measurement unit, controller 1025 may compute all inertial and spatial calculations from the IMU located on eyewear device 1002. A connector may convey information between augmented-reality system 1000 and neckband 1005 and between augmented-reality system 1000 and controller 1025. The information may be in the form of optical data, electrical data, wireless data, or any other transmittable data form. Moving the processing of information generated by augmented-reality system 1000 to neckband 1005 may reduce weight and heat in eyewear device 1002, making it more comfortable to the user.

Power source 1035 in neckband 1005 may provide power to eyewear device 1002 and/or to neckband 1005. Power source 1035 may include, without limitation, lithium-ion batteries, lithium-polymer batteries, primary lithium batteries, alkaline batteries, or any other form of power storage. In some cases, power source 1035 may be a wired power source. Including power source 1035 on neckband 1005 instead of on eyewear device 1002 may help better distribute the weight and heat generated by power source 1035.

FIG. 11 is an illustration of an exemplary virtual-reality headset that may be used in connection with embodiments of this disclosure. As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1100 in FIG. 11, that mostly or completely covers a user's field of view. Virtual-reality system 1100 may include a front rigid body 1102 and a band 1104 shaped to fit around a user's head. Virtual-reality system 1100 may also include output audio transducers 1106(A) and 1106(B). Furthermore, while not shown in FIG. 11, front rigid body 1102 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 1000 and/or virtual-reality system 1100 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 1000 and/or virtual-reality system 1100 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 1000 and/or virtual-reality system 1100 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A semiconductor device package, comprising:
a compute chip configured to perform contextual artificial intelligence and machine perception operations;
a sensor positioned above the compute chip in the semiconductor device package; and
one or more electrical connections configured to facilitate communication between the compute chip and the sensor, between the compute chip and a printed circuit board, and between the sensor and the printed circuit board.

2. The semiconductor device package of claim 1, wherein the one or more electrical connections include wire bonding of the sensor and the compute chip to printed circuit board.

3. The semiconductor device package of claim 1, wherein the one or more electrical connections include wire bonding of the sensor to the printed circuit board and face down mounting of the compute chip to the printed circuit board.

4. The semiconductor device package of claim 1, wherein the one or more electrical connections include one or more redistribution layers positioned between the sensor and the compute chip, wire bonding of the sensor to the one or more redistribution layers, wire bonding of the sensor to the printed circuit board, and wire bonding of the one or more redistribution layers to the printed circuit board.

5. The semiconductor device package of claim 1, wherein the one or more electrical connections include a package substrate positioned below the compute chip in the semiconductor device package, face down mounting of the compute chip to the package substrate, and wire bonding of the sensor to the package substrate.

6. The semiconductor device package of claim 1, wherein the one or more electrical connections include a package substrate positioned between the sensor and the compute chip in the semiconductor device package, mounting of the compute chip to the package substrate, and wire bonding of the sensor to the package substrate.

7. The semiconductor device package of claim 1, wherein the one or more electrical connections include a first set of one or more redistribution layers positioned between the sensor and the compute chip, a second set of one or more redistribution layers positioned below the compute chip, wire bonding of the sensor to the first set of one or more redistribution layers, and face down mounting of the compute chip to the second set of one more redistribution layers.

8. The semiconductor device package of claim 1, wherein the one or more electrical connections include one or more redistribution layers positioned below the compute chip, wire bonding of the sensor to the one or more redistribution layers, and face down mounting of the compute chip to the one more redistribution layers.

9. The semiconductor device package of claim 1, wherein the one or more electrical connections include a first set of one or more redistribution layers positioned between the sensor and the compute chip, a second set of one or more redistribution layers positioned below the compute chip, though silicon via connection of the sensor to the first set of one or more redistribution layers, and face down mounting of the compute chip to the second set of one more redistribution layers.

10. The semiconductor device package of claim 1, wherein the one or more electrical connections include one or more redistribution layers positioned between the sensor and the compute chip, a package substrate positioned between the one or more redistribution layers, though silicon via connection of the sensor to the one or more redistribution layers, and mounting of the compute chip to the package substrate.

11. The semiconductor device package of claim 1, wherein the one or more electrical connections include one or more redistribution layers positioned between the sensor and the compute chip, though silicon via connection of the sensor to the one or more redistribution layers, and mounting of the compute chip to the one or more redistribution layers.

12. A semiconductor device, comprising:
a compute chip configured to perform contextual artificial intelligence and machine perception operations; and
a sensor attached above the compute chip.

13. The semiconductor device of claim 12, wherein the sensor is attached to the compute chip by an adhesive.

14. The semiconductor device of claim 12, wherein the sensor is attached by an adhesive to one or more redistribution layers positioned between the sensor and the compute chip.

15. The semiconductor device of claim 12, wherein the sensor is attached by an adhesive to a package substrate positioned between the sensor and the compute chip.

16. The semiconductor device of claim 12, wherein the sensor is attached by through silicon vias to a first set of one or more redistribution layers mounted atop a second set of redistribution layers positioned between the sensor and the compute chip.

17. The semiconductor device of claim 12, wherein the sensor is attached by through silicon vias to one or more redistribution layers mounted atop a package substrate positioned between the sensor and the compute chip.

18. The semiconductor device of claim 12, wherein the sensor is attached by through silicon vias to one or more redistribution layers positioned between the sensor and the compute chip.

19. The semiconductor device of claim 12, further comprising:
a first connector configured to connect the semiconductor device to a system on chip; and
a second connector configured to connect the semiconductor device to another sensor.

20. A method comprising:
positioning a sensor, in a semiconductor device package, above a compute chip configured to perform contextual artificial intelligence and machine perception operations; and
configuring one or more electrical connections to facilitate communication between the compute chip and the sensor, between the compute chip and a printed circuit board, and between the sensor and the printed circuit board.
